(19) United States
(12) Patent Application Publication
(10) Pub. No.: US 2010/0270622 A1
(43) Pub. Date: Oct. 28, 2010

(54) Semiconductor Device Having a Strain Inducing Sidewall Spacer and a Method of Manufacture Therefor

(75) Inventors: Mahalingam NANDAKUMAR, Richardson, TX (US); Wayne A. BATHER, Richardson, TX (US); Narendra Singh MEHTA, Dallas, TX (US); Lahir Shaik ADAM, Plano, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/831,815

(22) Filed: Jul. 7, 2010

Related U.S. Application Data
(63) Continuation of application No. 11/610,908, filed on Dec. 14, 2006.
Application No. 11/610,908 is a continuation of application No. 11/344,998, filed on Feb. 1, 2006.

(51) Int. Cl. H01L 27/088; H01L 21/28; H01L 21/336

(52) U.S. Cl. 257/368; 438/595; 438/303; 257/E21.19; 257/E21.409; 257/E27.06

(57) ABSTRACT

The present invention provides a method for manufacturing a semiconductor device as well as a semiconductor device. The method, among other steps, may include forming a gate structure over a substrate, and forming a strain inducing sidewall spacer proximate a sidewall of the gate structure, the strain inducing sidewall configured to introduce strain in a channel region below the gate structure.

### CROSS-REFERENCE TO RELATED APPLICATIONS

This application is a continuation of U.S. application Ser. No. 11/344,998 filed on Feb. 1, 2006, entitled AA SEMICONDUCTOR DEVICE HAVING A HIGH CARBON CONTENT STRAIN INDUCING FILM AND A METHOD OF MANUFACTURE THEREFOR,@ commonly assigned with the present invention and incorporated herein by reference.

### TECHNICAL FIELD OF THE INVENTION

The present invention is directed, in general, to a semiconductor device and, more specifically, to a semiconductor device having a strain inducing sidewall spacer and a method of manufacture therefore.

### BACKGROUND OF THE INVENTION

There exists a continuing need to improve semiconductor device performance and further scale semiconductor devices. A characteristic that limits scalability and device performance is electron and/or hole mobility (e.g., also referred to as channel mobility) throughout the channel region of transistors. As devices continue to shrink in size, the channel region for transistors also continues to shrink in size, which can limit channel mobility.

One technique that may improve scaling limits and device performance is to introduce strain into the channel region, which can improve electron and/or hole mobility. Different types of strain, including uniaxial or biaxial tensile strain, compressive strain, etc. have been introduced into channel regions of various types of transistors in order to utilize their effect on electron and/or hole mobility. For some devices, certain types of strain improve mobility whereas other types degrade mobility.

FIG. 1 illustrates a conventional semiconductor device 100 at a stage of fabrication wherein a tensile strain is introduced by a silicon nitride cap-annealing process. The semiconductor device 100 includes a substrate 110 having a well region 120 located therein. The semiconductor device 100 further includes a gate structure 130 located over the substrate 110. The gate structure 130, as appreciated, includes both a gate dielectric layer 133 and a gate electrode layer 138.

Positioned on both sides of the gate structure 130 are source/drain sidewall spacers 140. Additionally positioned in the substrate 110 proximate the gate structure 130 are source/drain regions 150. The source/drain regions 150 therefore define a channel region 160 in the substrate 110.

After the source/drain regions 150 have been formed by implanting a suitable dopant, such as arsenic in the instant case, a strain-inducing layer 170 is deposited over the substrate 110 and gate structure 130. Then, a rapid thermal anneal is performed at a relatively high temperature, introducing and locking strain 180 into the channel region 160. The strain-inducing layer 170 is then removed and silicide regions (not shown) are typically formed on the source/drain regions 150 and gate electrode layer 138. A suitable silicide process is a conventional cobalt, nickel or other similar metal salicide process.

Compressive stress from the gate electrode layer 138 is enhanced by the annealing process described above, which introduces strain 180 (e.g., tensile) across the channel region 160. This strain 180 can improve the performance of the semiconductor device 100 by improving hole and/or electron mobility in the channel region 160. The cap-annealing process described supra can show improvement for, among others, NMOS devices. Unfortunately, it has been observed that the introduction of strain into the channel region using such a strain-inducing layer is insufficient to support some of the next generation devices.

Accordingly, what is needed in the art is an improved method for manufacturing a semiconductor device, and a device

### SUMMARY OF THE INVENTION

To address the above-discussed deficiencies of the prior art, the present invention provides a method for manufacturing a semiconductor device as well as a semiconductor device. The method, among other steps, may include forming a gate structure over a substrate, and forming a strain inducing sidewall spacer proximate a sidewall of the gate structure, the strain inducing sidewall spacer configured to introduce strain in a channel region below the gate structure.

The present invention further provides a method for manufacturing an integrated circuit. This method, in one embodiment, includes (1) forming gate structures over a semiconductor substrate, wherein each of the gate structures includes a gate dielectric and a gate electrode, (2) forming source/drain regions in the semiconductor substrate, wherein the source/drain regions are located proximate each of the gate structures, (3) forming a strain inducing sidewall spacer proximate a sidewall of each of the gate structures, (4) annealing the strain inducing sidewall spacers to introduce strain in a channel region located below each of the gate structures, the channel regions defined by the source/drain regions, and (5) forming interconnects within dielectric layers located over the gate structures, the interconnects contacting the gate structure or source/drain regions.

The present invention additionally provides a semiconductor device. The semiconductor device, without limitation, may include a gate structure located over a substrate, and a strain inducing sidewall spacer located proximate a sidewall of the gate structure, the strain inducing sidewall spacer configured to introduce strain in a channel region below the gate structure.

### BRIEF DESCRIPTION OF THE DRAWINGS

For a more complete understanding of the present invention, reference is now made to the following descriptions taken in conjunction with the accompanying drawings, in which:

Prior Art FIG. 1 illustrates a conventional semiconductor device at a stage of fabrication wherein a compressive strain is introduced by a conventional cap-annealing process;

FIGS. 2-8 illustrate detailed manufacturing steps showing how one might manufacture a semiconductor device in accordance with one embodiment of the invention; and

FIG. 9 illustrates an integrated circuit (IC) incorporating a semiconductor device constructed according to one embodiment of the invention.

### DETAILED DESCRIPTION

The present invention is based, at least in part, on the recognition that gate sidewall spacers may be designed to introduce strain in a channel region below a gate structure. From this recognition, the present invention acknowledges that various different gate sidewall spacers can be designed to introduce the strain in the channel region. For example, the present invention acknowledges that by increasing the ratio of bis t-butylaminosilane (BTBAS) to ammonia (NH₃) during the formation of silicon nitride gate sidewall spacers to a value of 1:1 or greater, the carbon concentration in the BTBAS silicon nitride layer can be increased. As the carbon concentration in the BTBAS silicon nitride layer is increased, the stress therein is also increased, thereby increasing the strain in the underlying silicon (e.g., the channel region).

The present invention has conducted many different experiments and determined that the aforementioned BTBAS to ammonia ratio can provide a peak carbon concentration of about 1.1E21 atoms/cm³ or greater, or even 2.0E21 atoms/cm³ or greater, resulting in a stress value of 1.25 GPa or greater. The present invention has further acknowledged that the increase in stress in the BTBAS silicon nitride layer also increases the resulting boron concentration in the substrate of the semiconductor device (e.g., for a given original boron dose and concentration). The increase in Boron concentration results in less source/drain resistance and increased transistor performance. Specifically, it is believed that the higher stress in the BTBAS silicon nitride layer reduces the boron outdiffusion from the substrate.

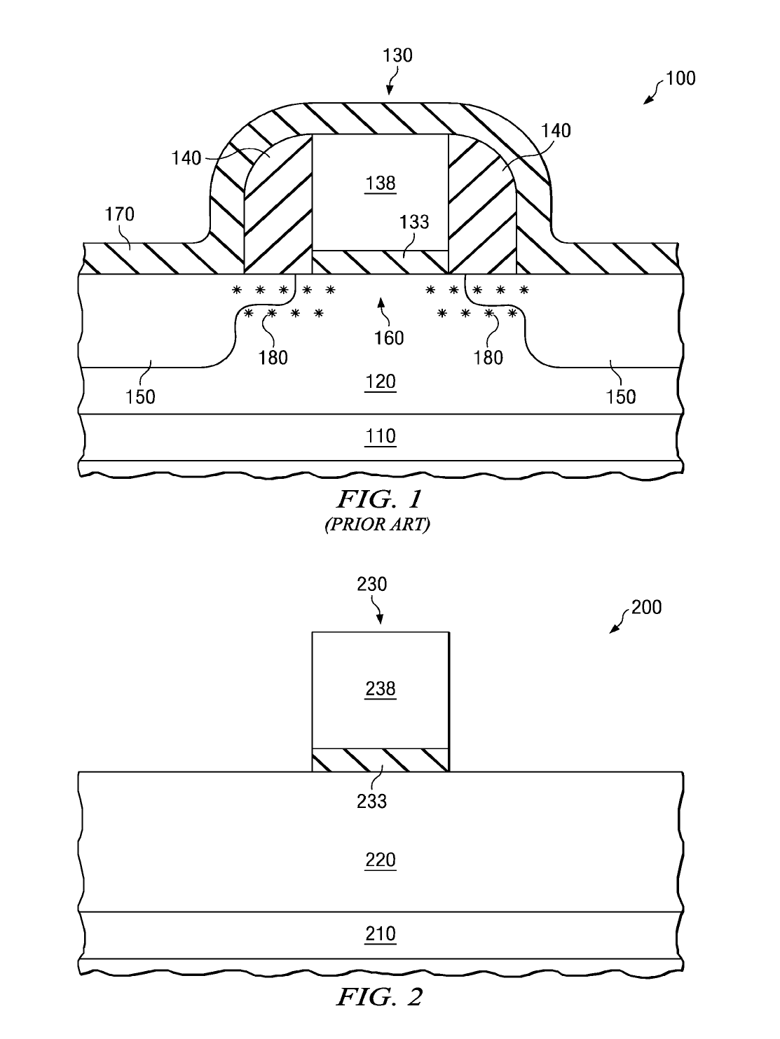

Turning now to FIGS. 2-8, illustrated are views of detailed manufacturing steps showing how one might manufacture a semiconductor device in accordance with one embodiment of the invention. FIG. 2 illustrates a semiconductor device 200 at an initial stage of manufacture. From the outset, it should be noted that the embodiment of FIGS. 2-8 will be discussed as an re-channel metal oxide semiconductor (NMOS) device. In an alternative embodiment, all the dopant types, except for possibly the substrate dopant, could be reversed, resulting in a p-channel metal oxide semiconductor (PMOS) device. However, at least with regard to FIGS. 2-8, no further reference to this opposite scheme will be discussed.

In the embodiment shown, the semiconductor device 200 of FIG. 2 includes a substrate 210. The substrate 210 may, in one embodiment, be any layer located in the semiconductor device 200, including a wafer itself or a layer located above the wafer (e.g., epitaxial layer). The substrate 210 of FIG. 1, however, is a P-type substrate. Nevertheless, one skilled in the art understands that the substrate 210 could also be an N-type substrate.

Located within the substrate 210 is a well region 220. The well region 220 contains a P-type dopant. For example, the well region 220 would likely be doped with a P-type dopant dose ranging from about 1E13 atoms/cm² to about 1E14 atoms/cm² and at an energy ranging from about 100 keV to about 500 keV. This may result in the well region 220 having a peak dopant concentration ranging from about 5E17 atoms/cm³ to about 1E19 atoms/cm³. Those skilled in the art understand that in certain circumstances where the P-type substrate 210 dopant concentration is high enough, the well region 220 may be excluded.

Located over the substrate 210 is a gate structure 230. The gate structure 230 includes a gate dielectric 233 and a gate electrode 238. The gate dielectric 233 may comprise a number of different materials and stay within the scope of the invention. For example, the gate dielectric 233 may comprise silicon dioxide, or in an alternative embodiment comprise a high dielectric constant (K) material. In the illustrative embodiment of FIG. 2, however, the gate dielectric 233 is a silicon dioxide layer having a thickness ranging from about 0.5 nm to about 5 nm.

Any one of a plurality of manufacturing techniques could be used to form the gate dielectric 233. For example, the gate dielectric 233 may be either grown or deposited. Additionally, the growth or deposition steps may require a

While the embodiment of FIG. 2 discloses that the gate electrode 238 comprises standard polysilicon, other embodiments exist where the gate electrode 238, or at least a portion thereof, comprises amorphous polysilicon material, a metal material, or fully silicided metal material. The amorphous polysilicon embodiment may be particularly useful when a substantially planar upper surface of the gate electrode 238 is desired.

The deposition conditions for the gate electrode 238 may vary. However, if the gate electrode 238 were to comprise standard polysilicon, such as the instance in FIG. 2, the gate electrode 238 could be deposited using a pressure ranging from about 100 torr to about 300 torr, a temperature ranging from about 620° C. to about 700° C., and a SiH₄ or Si₂H₆ gas flow ranging from about 50 sccm to about 150 sccm. If, however, amorphous polysilicon were desired, the amorphous polysilicon gate electrode could be deposited using a pressure ranging from about 100 torr to about 300 torr, a temperature ranging from about 450° C. to about 550° C., and a SiH₄ or Si₂H₆ gas flow ranging from about 100 sccm to about 300 sccm. In any instance, the gate electrode 238 may have a thickness ranging from about 50 nm to about 150 nm, among others.

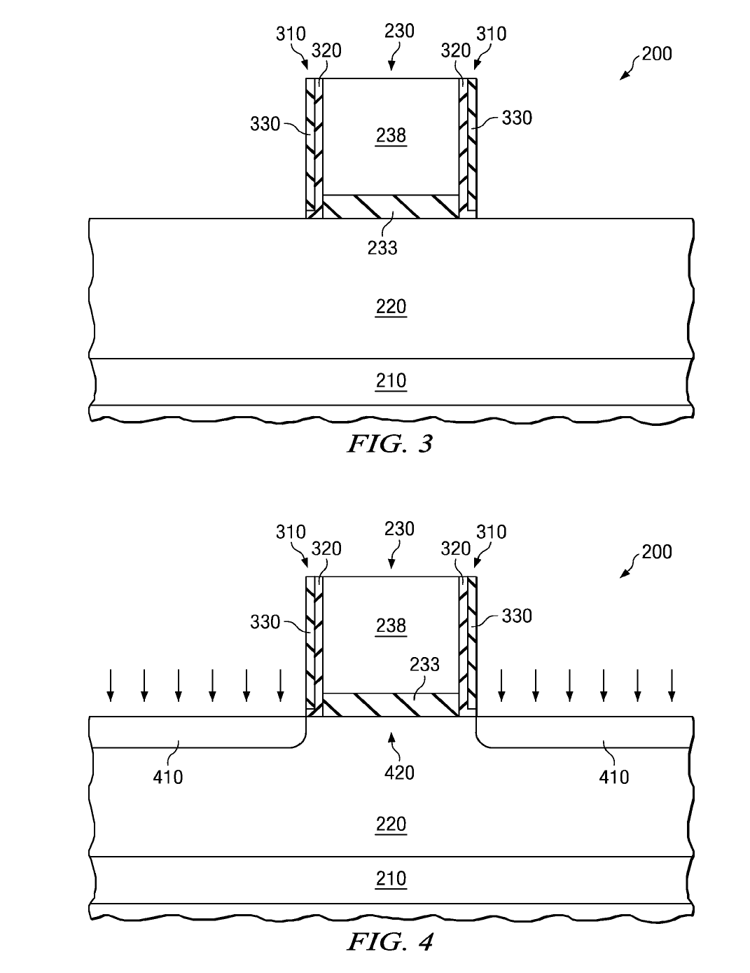

FIG. 3 illustrates the semiconductor device 200 of FIG. 2 after formation of portions of gate sidewall spacers 310. In accordance with the invention, any or all portions of the gate sidewall spacers 310 may be strain inducing sidewall spacers configured to introduce strain in a channel region below the gate structure 230. In those embodiments where later formed layers are configured to induce the strain, the earlier formed layers should, in one embodiment, be configured to transfer the strain of the later filed layers into the channel region. This is as compared to absorbing the strain of the later filed layers, as a conventional buffer layer might do. Those skilled in the art appreciate that the thickness of the earlier formed layers, as well as their material composition, may be adjusted to accommodate the transfer of strain to the channel region. The portions of the gate sidewall spacers 310 shown in FIG. 3 include an oxide offset spacer 320 and a nitride offset spacer 330.

The oxide offset spacer 320, if used as a strain inducing sidewall spacer, would typically have a stress value of about 0.5 GPa or greater, or in an alternative embodiment an even higher stress value of about 2.0 GPa or greater. For instance, the oxide offset spacer 320 might comprise a BTBAS oxide layer, or alternatively another oxide layer, while providing such stress values. In the embodiment wherein the oxide offset spacer 320 comprises a BTBAS oxide layer, it might have a peak carbon concentration of about 1.1E21 atoms/cm³ or greater. In an alternative embodiment, the BTBAS oxide layer might have a peak carbon concentration of about 1.5E21 atoms/cm³ or greater, or even a peak carbon concentration of about 2.0E21 atoms/cm³ or greater. The aforementioned peak carbon concentration values are particularly beneficial in providing significant improvement in the stress values of the oxide offset spacer 320.

The BTBAS oxide layer might be deposited using a chemical vapor deposition (CVD) process to a thickness ranging from about 1 nm to about 50 nm. In the specific embodiment shown in FIG. 3, the BTBAS oxide layer might be deposited using a non-plasma CVD process to a thickness ranging from about 2.0 nm to about 10 nm. The temperature maintained during the formation of the BTBAS oxide layer in this embodiment should remain relatively low, for example a temperature of less than about 600° C. In an alternative embodiment, the temperature remains between about 500° C. and about 550° C. Likewise, the pressure used during the formation of the BTBAS oxide layer would desirably range from about 100 mTorr to about 1 Torr.

In the embodiment wherein the oxide offset spacer 320 does not comprise the BTBAS oxide layer but a non BTBAS oxide layer configured as a strain inducing layer, the non BTBAS oxide layer might also be formed using a CVD process. For example, the non BTBAS oxide layer might be formed using the CVD process to a thickness ranging from about 2.0 nm to about 10 nm. It is important in this embodiment that the temperature maintained during the formation of the non BTBAS oxide layer should also remain low in order to provide the desired tensile stress therein. For instance, a temperature of less than about 600° C. should be used. In those embodiments wherein a desire does not exist for the oxide offset spacer 320 to function as a strain inducing sidewall spacer, the oxide offset spacer 320 might be conventionally formed, for example possibly using conventional growth, deposition or a combination of growth and deposition steps.

The nitride offset spacer 330, which as previously discussed may function as a strain inducing film, might comprise a BTBAS silicon nitride layer while remaining within the purview of the present invention. When used, the BTBAS silicon nitride layer might have a peak carbon concentration of about 1.1E21 atoms/cm³ or greater. In an alternative embodiment, the BTBAS silicon nitride layer might have a peak carbon concentration of about 1.5E21 atoms/cm³ or greater, or even a peak carbon concentration of about 2.0E21 atoms/cm³ or greater. What results with such peak carbon concentrations is the BTBAS silicon nitride layer having the aforementioned stress values.

The BTBAS silicon nitride layer would typically be deposited using a CVD process to a thickness ranging from about 1 nm to about 50 nm. In the specific embodiment shown in FIG. 3, the BTBAS silicon nitride layer would typically be deposited using a non-plasma CVD process to a thickness ranging from about 2.0 nm to about 10 nm. The BTBAS silicon nitride layer, as compared to conventional BTBAS silicon nitride layers, may be formed using a ratio of BTBAS to ammonia (NH₃) of about 1:1 or greater. In other embodiments, however, the BTBAS silicon nitride layer is formed using a ratio of BTBAS to ammonia (NH₃) of about 2:1 or greater, or even 4:1 or greater, depending on the desired amount of carbon. The temperature maintained during the formation of the BTBAS silicon nitride layer should remain relatively low, for example a temperature of less than about 600° C. In an alternative embodiment, the temperature remains between about 500° C. and about 550° C. Likewise, the pressure used during the formation of the BTBAS silicon nitride layer would desirably range from about 100 mTorr to about 1 Torr.

The nitride offset spacer 320 may, in an alternative embodiment, be formed using a plasma enhanced CVD (PECVD) process. In this embodiment, the nitride offset spacer 320 might comprise silicon nitride. In those embodiments wherein a desire does not exist for the nitride offset spacer 330 to function as a strain inducing sidewall spacer, the nitride offset spacer 330 might be conventionally formed.

While the oxide offset spacer 320 and the nitride offset spacer 330 are shown located only along the sides of the gate structure 230, those skilled in the art are aware that the layers may have been previously blanket formed (e.g., along an upper surface of a substantial portion of the semiconductor device 200) and subsequently anisotropically etched to form the oxide offset spacer 320 and the nitride offset spacer 330.

FIG. 4 illustrates the semiconductor device 200 of FIG. 3 after formation of source/drain extension implants 410 within the substrate 210. The implants 410 may be conventionally formed and generally have a peak dopant concentration ranging from about 1E19 atoms/cm³ to about 2E20 atoms/cm³. As is standard in the industry, the implants 410 may have a dopant type opposite to that of the well region 220 they are located within. Accordingly, the implants 410 are doped with an N-type dopant, thereby forming a channel region 420.

FIG. 5 illustrates the semiconductor device 200 of FIG. 4 after forming additional portions of the gate sidewall spacers 310. Particularly, a cap oxide 510, L-shaped source/drain spacers 520 and bulk source/drain spacers 530 complete the gate sidewall spacers 310 in this embodiment. Again, any one or all of the cap oxide 510, L-shaped source/drain spacers 520 and bulk source/drain spacers 530 may be designed to be strain inducing gate sidewall spacers. The cap oxide 510, in addition to

In the embodiment wherein it is desired for the cap oxide 510 to be a strain inducing sidewall spacer, it might be formed using a process similar to that used to form the oxide offset spacer 320 when it was designed as a strain inducing sidewall spacer. In the embodiment wherein it is not desired for the cap oxide 510 to be a strain inducing sidewall spacer, it might be formed using a process similar to that used to form the oxide offset spacer 320 when it was not designed as a strain inducing sidewall spacer.

The L-shaped source/drain spacers 520 may, depending on whether they are designed as strain inducing sidewall spacers, be formed using many different processes and materials. For instance, in the embodiment wherein it is desired for the L-shaped source/drain spacers 520 to be strain inducing sidewall spacers, they might be formed using similar materials and processes as used to form the nitride offset spacers 330 when they were designed as strain inducing sidewall spacers. In the embodiment wherein it is not desired for the L-shaped source/drain spacers 520 to be strain inducing sidewall spacers, they might be formed using similar materials and processes as used to form the nitride offset spacers 330 when they were not designed as strain inducing sidewall spacers.

The bulk source/drain spacers 530 may also, depending on whether they are designed as strain inducing sidewall spacers, be formed using many different processes and materials. For instance, in the embodiment wherein it is desired for the bulk source/drain spacers 530 to be strain inducing sidewall spacers, they might be formed using similar materials and processes as used to form the oxide offset spacers 320 when they were designed as strain inducing sidewall spacers. In the embodiment wherein it is not desired for the bulk source/drain spacers 530 to be strain inducing sidewall spacers, they might be formed using similar materials and processes as used to form the oxide offset spacers 320 when they were not designed as strain inducing sidewall spacers.

Typically, the layers of the gate sidewall spacers 310 will alternate between different materials, for example the alternating oxide and nitride layers of FIGS. 3-5. Thus, multiple films comprising an oxide or multiple films comprising a nitride, such as shown in the discussed FIGS. will not generally be located on one another. That being said, however, in the embodiment shown in FIG. 5, those layers that were described as oxides could be exchanged for nitrides, and vice-versa.

While a substantial amount of detail has been given regarding the specifics of the gate sidewall spacers 310, such should not be construed to be limiting on the present invention. For example, certain embodiments exist where only the nitride offset spacer 330 and bulk source/drain spacers 530, or another similar structure, comprise the gate sidewall spacers 310. Other embodiments exist where all the layers shown in FIG. 5 exist, however, the materials and thicknesses are different. In another embodiment of the invention, the material chosen for the gate sidewall spacers 310 is based on its disposable nature. Therefore, as previously noted, the details given with respect to FIGS. 3 and 5 regarding the gate sidewall spacers 310 should not be used to limit the scope of the present invention.

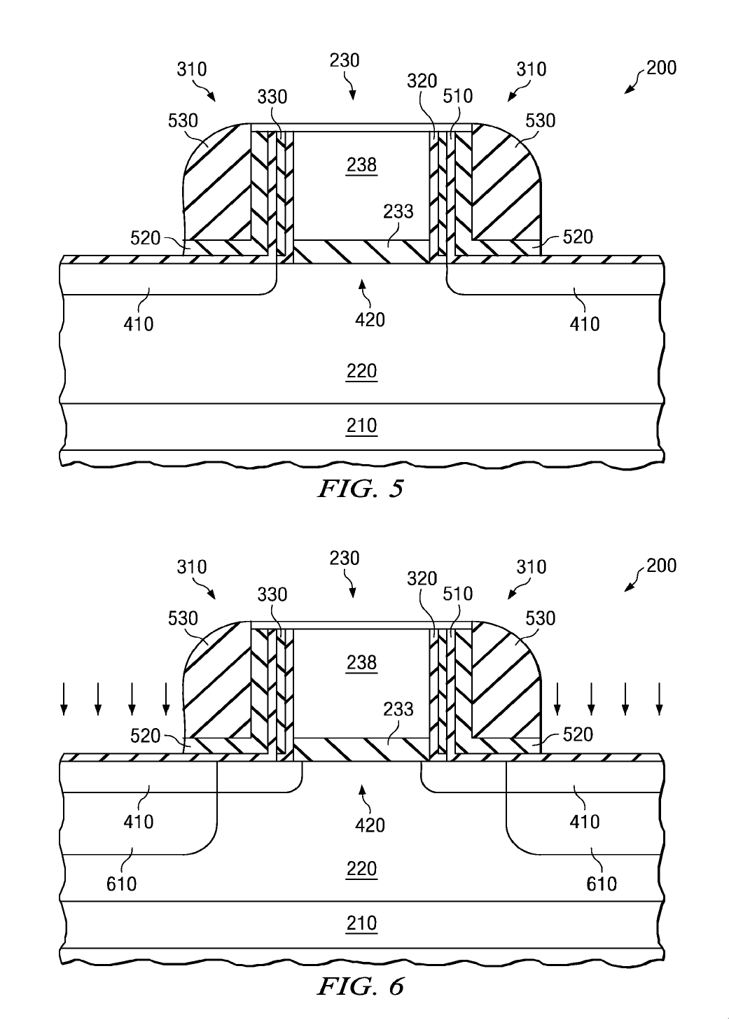

FIG. 6 illustrates the semiconductor device 200 of FIG. after forming source/drain implants 610 within the substrate 210. Those skilled in the art understand that conventional processes might be used to form the implants 610. Generally, the implants 610 have a peak dopant concentration ranging from about 1E18 atoms/cm³ to about 1E21 atoms/cm³. Also, the implants 610 should typically have a dopant type opposite to that of the well region 220 they are located within. Accordingly, in the illustrative embodiment shown in FIG. 6, the implants 610 are doped with an N-type dopant.

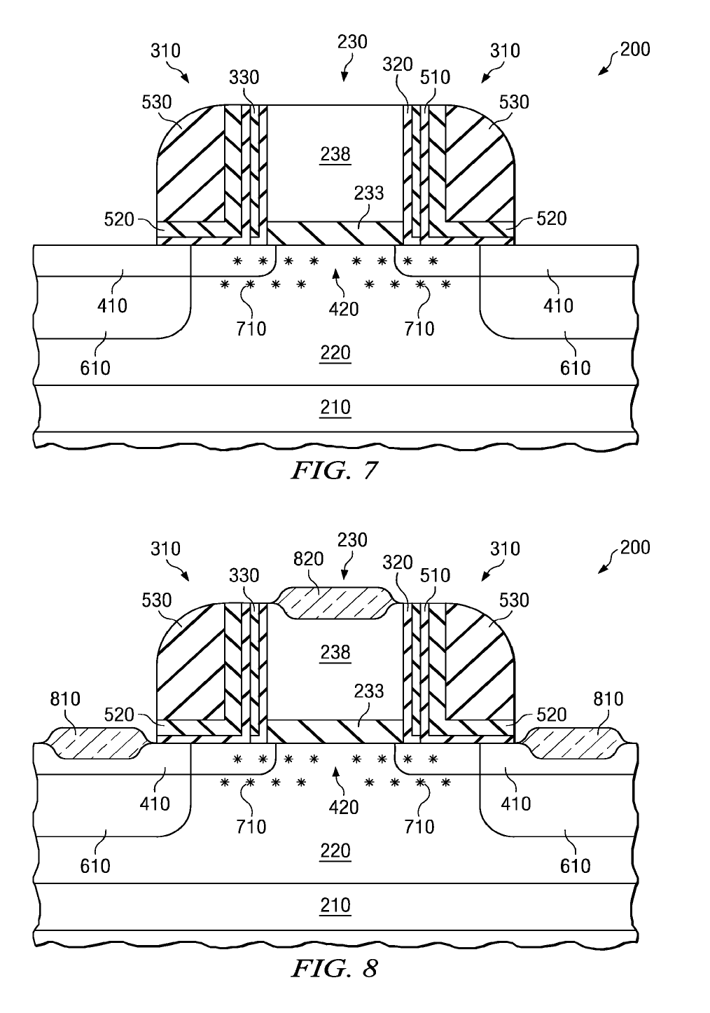

FIG. 7 illustrates the semiconductor device 200 of FIG. 6 after subjecting it to a thermal anneal. In the embodiment shown, the thermal anneal imparts a strain 710 into the substrate 210, particularly the channel region 420. The thermal anneal, which happens to be a rapid thermal anneal in the illustrative embodiment of FIG. 7, may be performed at a temperature of greater than about 350° C., and less than about 1100° C., for a time period of less than about 180 seconds. In an alternative embodiment, however, the anneal can be conducted as a spike anneal or millisecond anneal (e.g., laser, flash, etc.) at a temperature ranging from about 800° C. to about 1400° C. The anneal may furthermore be a combination of the aforementioned anneals. The timing of the anneal, particularly in this embodiment, allows the later formed silicided source/drain regions 810 and a silicided gate electrode layer 820 to not be affected thereby.

The semiconductor device 200 resulting after the anneal of FIG. 7 has a number of benefits over conventional devices. One such benefit is the increased strain 710 that results in the channel region 420 as a result of the use of one or more strain inducing sidewall spacers. Another benefit is the increased boron concentration in the channel region 420, and thus decreased resistance therein, that results from the use of one or more strain inducing sidewall spacers. Not only does the resulting semiconductor device 200 benefit from the manufacturing process of the present invention, but existing hardware and processing steps may be used, which reduces the time and cost associated with introducing the novel aspects of the present invention. Likewise, the use of the inventive aspects of the invention allow for a lower thermal budget, at least as compared to other alternatives that do not comprise the one or more strain inducing sidewall spacers.

FIG. 8 illustrates the semiconductor device 200 of FIG. after forming silicided source/drain regions 810 and a silicided gate electrode layer 820. The skilled artisan understands the silicided source/drain region 810 and silicided gate electrode layer 820 formation process. In sum, the process may include forming a metal layer, possibly cobalt, nickel, nickel platinum etc., over the substrate 210 and gate structure 230, and subjecting the metal layer to an anneal, causing the metal to react with the silicon of the substrate 210, and in this instance the gate electrode layer 238, and form the silicided source/drain regions 810 and silicided gate electrode layer 820.

It should be noted that FIGS. 7-8 illustrate that the silicided source/drain regions 810 and a silicided gate electrode layer 820 are formed after the anneal that forms the strain 710. However, another embodiment exists wherein the anneal is conducted after the formation of the silicided source/drain regions 810 and silicided gate electrode layer 820. Accordingly, the present invention should not be limited to any specific order in the formation of the silicided source/drain regions 810 and a silicided gate electrode layer 820, and the anneal.

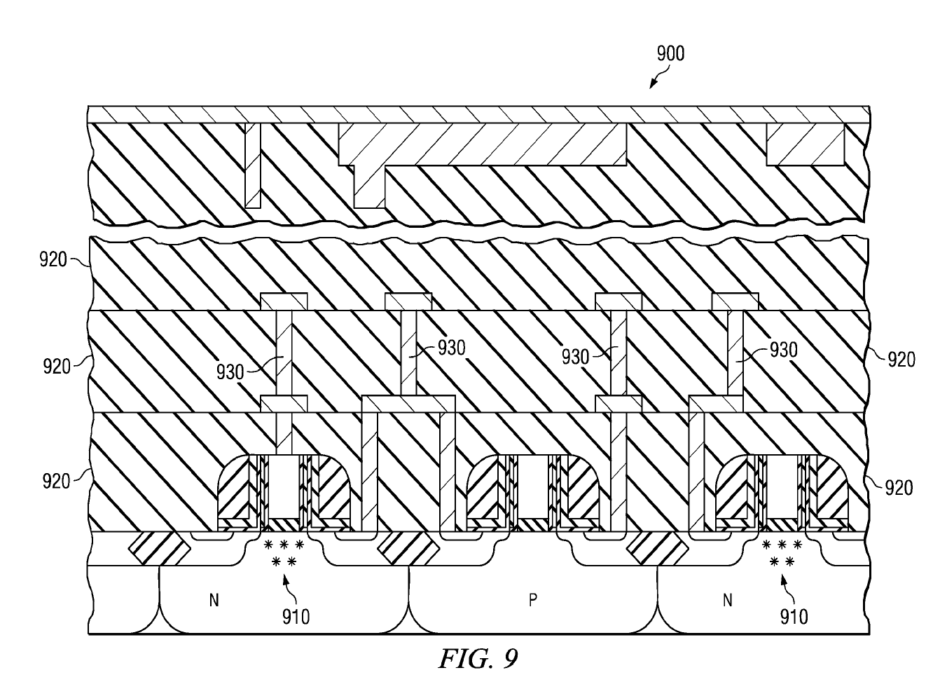

FIG. 9 illustrates an integrated circuit (IC) 900 incorporating a semiconductor device 910 constructed according to the principles of the invention. The IC 900 may include devices, such as transistors used to form CMOS devices, BiCMOS devices, Bipolar devices, or other types of devices. The IC 900 may further include passive devices, such as inductors or resistors, or it may also include optical devices or optoelectronic devices. Those skilled in the art are familiar with these various types of devices and their manufacture. In the particular embodiment illustrated in FIG. 9, the IC 900 includes semiconductor devices 910 having dielectric layers 920 located thereover. Additionally, interconnect structures 930 are located within the dielectric layers 920 and contacting the semiconductor devices 910, thus, forming the integrated circuit 900.

Although the present invention has been described in detail, those skilled in the art should understand that they could make various changes or substitutions herein without departing from the invention.

1. A method for manufacturing a semiconductor device, comprising:
forming a gate structure over a substrate; and
forming a strain inducing sidewall spacer proximate a sidewall of the gate structure by depositing a spacer material and anisotropically etching the spacer material, the strain inducing sidewall spacer configured to introduce strain in a channel region below the gate structure.

2. The method as recited in claim 1 wherein the strain inducing sidewall spacer has a tensile stress of about 0.5 GPa or greater.

3. The method as recited in claim 1 wherein forming a strain inducing sidewall spacer includes forming a strain inducing sidewall spacer using a temperature of less than about 600° C.

4. The method as recited in claim 1 wherein the strain inducing sidewall spacer comprises a nitride.

5. The method as recited in claim 1 wherein the strain inducing sidewall spacers comprises a bis t-butylaminosilane (BTBAS) silicon nitride layer formed using a flow ratio of bis t-butylaminosilane (BTBAS) to ammonia (NH₃) of 1:1 or greater.

6. The method as recited in claim 5 wherein the bis t-butylaminosilane (BTBAS) silicon nitride layer has a peak carbon concentration of about 1.1E21 atoms/cm³ or greater.

7. The method as recited in claim 5 wherein the bis t-butylaminosilane (BTBAS) silicon nitride layer is a first strain inducing sidewall spacer and further including forming a second strain inducing sidewall spacer, the second strain inducing sidewall spacer located proximate the first strain inducing sidewall spacer.

8. The method as recited in claim 7 wherein the second strain inducing sidewall spacer comprises an oxide, nitride or combination thereof.

9. (canceled)

10. A method for manufacturing an integrated circuit, comprising:
forming gate structures over a semiconductor substrate, wherein each of the gate structures includes a gate dielectric and a gate electrode;
forming source/drain regions in the semiconductor substrate, wherein the source/drain regions are located proximate each of the gate structures;
forming a strain inducing sidewall spacer proximate a sidewall of each of the gate structures by depositing a spacer material and anisotropically etching the spacer material to leave spacer material on said sidewall;
annealing the strain inducing sidewall spacers to introduce strain in a channel region located below each of the gate structures, the channel regions defined by the source/drain regions; and
forming interconnects within dielectric layers located over the gate structures, the interconnects contacting the gate structure or source/drain regions.

11. A semiconductor device, comprising:
a gate structure located over a substrate; and
a strain inducing sidewall spacer located proximate a sidewall of the gate structure without overlying the gate structure, the strain inducing sidewall spacer configured to introduce strain in a channel region below the gate structure.

12. The device as recited in claim 11 wherein the strain inducing sidewall spacer has a tensile stress of about 0.5 GPa or greater.

13. The device as recited in claim 11 wherein the strain inducing sidewall spacer comprises a nitride.

14. The device as recited in claim 11 wherein the strain inducing sidewall spacers comprises a bis t-butylaminosilane (BTBAS) silicon nitride layer.

15. The device as recited in claim 14 wherein the bis t-butylaminosilane (BTBAS) silicon nitride layer has a peak carbon concentration of about 1.1E21 atoms/cm³ or greater.

16. The device as recited in claim 14 wherein the bis t-butylaminosilane (BTBAS) silicon nitride layer is a first strain inducing sidewall spacer and further including a second strain inducing sidewall spacer located proximate the first strain inducing sidewall spacer.

17. The device as recited in claim 16 wherein the second strain inducing sidewall spacer comprises an oxide, nitride or combination thereof.

18. (canceled)

19. The device as recited in claim 11 wherein the strain inducing sidewall spacer is an offset spacer, an L-shaped spacer, a source/drain spacer or a bulk spacer.

20. The device as recited in claim 11 further including a dielectric layer having one or more interconnects therein located over the gate structure, the one or more interconnects contacting the gate structure to form an integrated circuit.
